(19) United States
(12) Patent Application Publication
(10) Pub. No.: US 2011/0203650 A1
(43) Pub. Date: Aug. 25, 2011

(54) OPTICAL CONVERTER DEVICE AND ELECTRONIC EQUIPMENT INCLUDING THE OPTICAL CONVERTER DEVICE

(75) Inventor: Masahiro FURUSAWA, Chino (JP)

(73) Assignee: SEIKO EPSON CORPORATION, Tokyo (JP)

(21) Appl. No.: 13/034,146

(22) Filed: Feb. 24, 2011

(30) Foreign Application Priority Data
Feb. 25, 2010 (JP) 2010-040607

(51) Int. Cl. H01L 31/06; H01L 31/18; B82Y 40/00

(52) U.S. Cl. 136/255; 438/96; 977/774; 257/E31.034

(57) ABSTRACT

A photovoltaic converter device includes a first conductivity type substrate (a p-type single crystalline silicon substrate 100), a first intermediate layer (an i-type semiconductor layer 110 or a dielectric layer 160), and a second conductivity type semiconductor layer (an n-type semiconductor layer 120). The first intermediate layer (the i-type semiconductor layer 110 or the dielectric layer 160) includes quantum dots (nanoparticles) having at least cores. The first conductivity type substrate is formed from crystalline semiconductor such as single crystalline silicon.

The entire disclosure of Japanese Patent Application No. 2010-040607, filed Feb. 25, 2010 is expressly incorporated by reference herein.

### BACKGROUND

1. Technical Field

The present invention relates to optical converter devices and, in particular, to photovoltaic converter devices using quantum dots.

2. Related Art

As clean energy sources that contribute to energy conservation and resource saving, solar cells (i.e., photovoltaic converter devices) are being actively developed. Solar cells are electric power devices that use the photo-electromotive force effect to directly convert light energy to electric power. As their structures, various kinds of structures, such as, organic thin film solar cells, dye-sensitized solar cells, solar cells with multi-junction structure, and the like are being investigated. Above all, so-called HIT (Heterojunction with Intrinsic Thin layer) solar cells, in which amorphous silicon layers are formed on mono crystalline silicon, have a structure that can achieve high efficiency, and HIT solar cells with module efficiency of 20% or more have been developed. For example, Japanese Laid-open Patent Application HEI 4-130671 (Patent Document 1) describes HIT solar cells.

Further, solar cells that use quantum dots (nanoparticles) are attracting attention as the next-generation solar cells that make it possible in theory to achieve the conversion efficiency higher than 60%. For example, Published Japanese translation of a PCT application 2007-535806 (Patent Document 2) describes a solar cell having a plurality of crystalline semiconductor material quantum dots that are separated from one another by dielectric material thin layers.

However, the cell described in Patent Document 1 has a single junction structure with one PN junction, and therefore its theoretical limit of conversion efficiency is about 25%, and it is difficult to achieve the conversion efficiency higher than this level.

With the structure examined in detail in Patent Document 2, it is feared that charge (electrons) cannot be effectively retrieved from the quantum wells. Patent Document 2 examines that, according to the super lattice structure described therein, mini-bands are formed so that charge (electrons) can be efficiently retrieved. However, a highly advanced technology is necessary to manufacture a device with the super lattice structure in which quantum dots are regularly arranged. Moreover, in order to form mini-bands, variations in the particle size need to be suppressed to less than 10% for quantum dots of several nm to several ten nm in diameter, which is also technically difficult.

### SUMMARY

In accordance with some aspects of the invention, it is possible to provide photovoltaic converter devices with excellent conversion efficiency without using complex technology.

In accordance with an embodiment of the invention, a photovoltaic converter device is equipped with a first conductivity type substrate including first conductivity type semiconductor, a first intermediate layer formed on the first conductivity type substrate, and a second conductivity type semiconductor layer including second conductivity type semiconductor and formed on the first intermediate layer. In one aspect, the first intermediate layer includes nanoparticles, and the nanoparticles have cores composed of a first material.

According to the photovoltaic converter device having such a structure, it is possible to provide a photovoltaic converter device equipped with the first intermediate layer including quantum dots, in a so-called HIT structure, without using a structure that requires high-level manufacturing technology, like the super lattice structure. Also, as the structure includes quantum dots, multiple exciton generation (MEG) would more readily occur, such that the photovoltaic converter device can be provided with excellent conversion efficiency.

In one aspect, at least a portion of the first conductivity type substrate may preferably be made of first conductivity type semiconductor, and at least a portion of the second semiconductor layer may preferably be made of second conductivity type semiconductor.

In another aspect, it is preferred that the nanoparticles may further have shells covering the cores and made of second material.

According to such a structure, the cores of the nanoparticles are coated by the shells composed of the second material, and contact the shells. Such a structure makes it possible to use, as the material of the cores, a material having an absorption coefficient greater than an absorption coefficient of a material composing the intermediate layer that contains the nanoparticles, such that higher photovoltaic conversion efficiency can be obtained.

It is preferred that the second material has a band gap that is greater than a band gap of the first material, and greater than a band gap of a third material included in the first intermediate layer.

According to such a structure, the band gap between the first material and the second material forms a quantum well, and charges within the quantum well can be readily retrieved by tunneling through the material that is in contact with the first material. Accordingly, the photovoltaic converter device is provided with higher conversion efficiency.

In accordance with an aspect of the invention, the first material may preferably have an absorption coefficient greater than an absorption coefficient of the third material.

According to such a structure, more light can be absorbed at the cores of the quantum dots than the first intermediate layer, by which the rate of MEG occurrences becomes greater, whereby the conversion efficiency of the photovoltaic converter device can be improved.

In accordance with an aspect of the invention, the first conductivity type substrate may be a single crystal silicon substrate or a polycrystalline silicon substrate of a first conductivity type, the third material may be i-type amorphous silicon, and the second conductivity type semiconductor layer may be formed from amorphous silicon of a second conductivity type.

Also, the first intermediate layer may include dielectric material.

An electronic apparatus in accordance with another embodiment of the invention includes any one of the photovoltaic converter devices described above.

In accordance with still another embodiment of the invention, a method for manufacturing a photovoltaic converter device includes the steps of forming a first intermediate layer on a first conductivity type substrate composed of semiconductor of a first conductivity type, and forming a second conductivity type semiconductor layer composed of semiconductor of a second conductivity type on the first intermediate layer. In one aspect, the first intermediate layer includes nanoparticles equipped with cores composed of a first material, and the first conductivity type semiconductor is crystalline semiconductor.

According to such a method, a photovoltaic converter device with excellent conversion efficiency can be manufactured by using relatively simple manufacturing technology.

Also, in the step of forming the second conductivity type semiconductor layer, the cores may preferably be formed in a manner to contact a material having a greater band gap than a band gap of the first material.

According to such a method, it is possible to manufacture a photovoltaic converter device in which the band gap between the first material and the material that contacts the first material forms a quantum well, and charges within the quantum well can be readily retrieved by tunneling through the material that is in contact with the first material. Accordingly, the photovoltaic converter device can be manufactured with higher conversion efficiency.

### BRIEF DESCRIPTION OF THE DRAWINGS

FIG. 1 is a cross-sectional view showing the structure of a photovoltaic converter device in accordance with Embodiment 1.

FIG. 2 is a cross-sectional view showing the structure of a quantum dot.

FIG. 3 is a first cross-sectional view showing a step of manufacturing the photovoltaic converter device in accordance with Embodiment 1.

FIG. 4 is a second cross-sectional view showing a step of manufacturing the photovoltaic converter device in accordance with Embodiment 1.

FIG. 5 is a third cross-sectional view showing a step of manufacturing the photovoltaic converter device in accordance with Embodiment 1.

FIG. 6 is a fourth cross-sectional view showing a step of manufacturing the photovoltaic converter device in accordance with Embodiment 1.

FIG. 7 is a cross-sectional view showing the structure of a photovoltaic converter device in accordance with Embodiment 2.

FIG. 8 is a cross-sectional view showing the structure of a photovoltaic converter device in accordance with Embodiment 3.

FIG. 9 is a plan view of a calculator using a photovoltaic converter device in accordance with an embodiment of the invention.

FIG. 10 is a plan view of a cellular phone using a photovoltaic converter device in accordance with an embodiment of the invention.

FIG. 11 is a plan view of a wrist watch using a photovoltaic converter device in accordance with an embodiment of the invention.

### DESCRIPTION OF EXEMPLARY EMBODIMENTS

Preferred embodiments of the invention are described in detail below with reference to the accompanying drawings, according to the following composition. However, the embodiments described below are merely examples of the invention, and do not limit the technical scope of the invention. It is noted that, in each of the drawings, the same components shall be appended with the same reference numbers, and their description may not be repeated.

1. Definition

2. Embodiment 1
(1) Exemplary Structure of Photovoltaic Converter Device
(2) Method for Manufacturing Photovoltaic Converter Device

3. Embodiment 2
(1) Exemplary Structure of Photovoltaic Converter Device

4. Embodiment 3
(1) Exemplary Structure of Photovoltaic Converter Device
(2) Method for Manufacturing Photovoltaic Converter Device

5. Characteristics of the Invention

6. Application Examples

### 1. Definition

First, terms to be used in the present specification will be defined as follows.

“Up” and “down”: In the present specification, an upward direction and a downward direction in the drawings shall be called “up” and “down,” respectively, in order to facilitate understanding. It is noted that any composition having a similar relation in laminated layers shall be included in the scope of the invention, though up and down of the actual composition may be reversed, or arranged sideways.

### 2. Embodiment 1

First, a photovoltaic converter device and a method for manufacturing the photovoltaic converter device in accordance with Embodiment 1 of the invention will be described with reference to the accompanying drawings.

(1) Exemplary Structure of Photovoltaic Converter Device

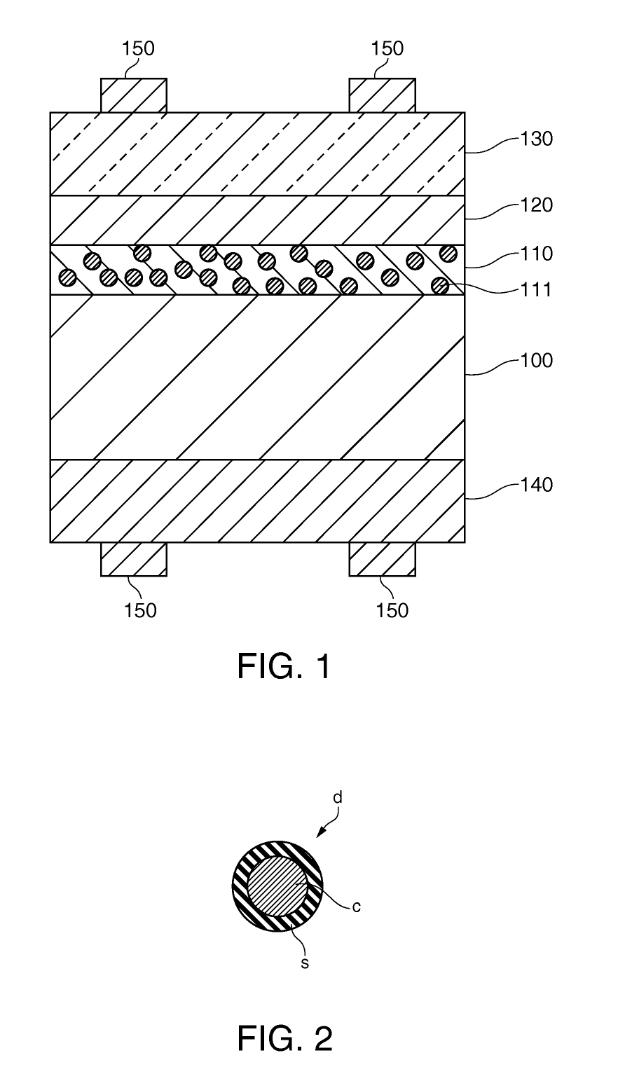

FIG. 1 is a cross-sectional view showing the structure of a photovoltaic converter device in accordance with Embodiment 1. As shown in FIG. 1, the photovoltaic converter device has a structure in which a p-type single crystalline silicon substrate 100 that is a p-type (first conductivity type) semiconductor substrate, an i-type semiconductor layer 110, and an n-type semiconductor layer 120 that is an n-type (second conductivity type) semiconductor layer are laminated in layers. Furthermore, the photovoltaic converter device in accordance with Embodiment 1 includes a transparent electrode 130 on the n-type semiconductor layer 120, and a metal electrode 140 below the p-type signal crystalline silicon substrate 100. Further, a plurality of collecting electrodes 150 is electrically connected to the transparent electrode 130, and a plurality of collecting electrodes 150 is electrically connected to the metal electrode 140.

Each of the first and second conductivity types corresponds to p-type or n-type. In the case of the p-type, p-type impurity such as boron (B) may be contained. In the case of the n-type, n-type impurity such as phosphor (P) may be contained. The i-type (intrinsic) layer means a layer with no impurity being injected, and having a lower impurity concentration compared to the p-type or n-type layer.

The p-type single crystalline silicon substrate 100 is formed from p-type single crystalline silicon, for example, in a thickness of 200 μm.

The i-type semiconductor layer 110 is formed from amorphous silicon, containing quantum dots (nanoparticles) 111 therein. FIG. 2 is a cross-sectional view of the quantum dot 111. The quantum dots 111 (d) used in Embodiment 1 have a core-shell structure, as shown in FIG. 2, and have cores c composed of material in particles, and shells s that cover outer circumferences of the cores c. In Embodiment 1, as an example, particles of lead sulfide (PbS) of 3 nm in diameter are used as the cores c, and silicon oxide (SiO₂) of 2 nm in thickness are used as the shells s. The thickness of the i-type semiconductor layer 110 may be, for example, 20 nm.

Core portions and their outer circumference shell portions of the quantum dots 111 may be manufactured by, for example, a molecular beam epitaxy, a chemical vapor deposition, a gas-evaporation deposition, a hot soap method, a colloidal wet chemical method or the like. For example, liquid containing quantum dots with a core-shell structure dispersed therein is manufactured and sold by Quantum Dot Corporation and Evident Technologies Inc. As the materials usable for the cores c, germanium (Ge) or lead selenide (PbSe) particles of 1 nm or more but 20 nm or less in diameter may be used, besides lead sulfide (PbS). The shells s may be in a thickness of 0.5 nm to 10 nm, and may be made from a material having a band gap greater than the band gap of the core c and the band gap of amorphous silicon forming the i-type semiconductor layer 110, for example, dielectric material such as silicon oxide (SiO₂).

The n-type semiconductor layer 120 is formed from amorphous silicon with n-type impurity injected therein. The thickness of the n-type semiconductor layer 120 may be, for example, 10 nm.

The transparent electrode 130 may be formed from, for example, indium tin oxide (ITO) in which indium is added to tin oxide, fluorine-doped tin oxide (FTO), indium oxide (IO), tin oxide (SnO₂), or the like. The thickness of the transparent electrode 130 may be, for example, 5 μm.

As the material for the metal electrode 140, for example, aluminum (Al) may be used. Other metal materials, such as, nickel (Ni), cobalt (Co), platinum (Pt), silver (Ag), gold (Au), copper (Cu), molybdenum (Mo), titanium (Ti) and tantalum (Ta) may be used. The thickness of the metal electrode may be, for example, 5 μm.

The collecting electrodes 150 connected to the transparent electrode 130 are constituted in such a manner that voltage generated by the solar cell is collected through the transparent electrode 130 in the collecting electrodes 150 and effectively retrieved to the outside. Also, the collecting electrodes 150 connected to the metal electrode 140 are constituted in such a manner that voltage generated by the solar cell is collected through the metal electrode 140 in the collecting electrodes 150 and effectively retrieved to the outside. As the collecting electrodes 150, conductive material such as silver (Ag) may be used.

(2) Method for Manufacturing Photovoltaic Converter Device

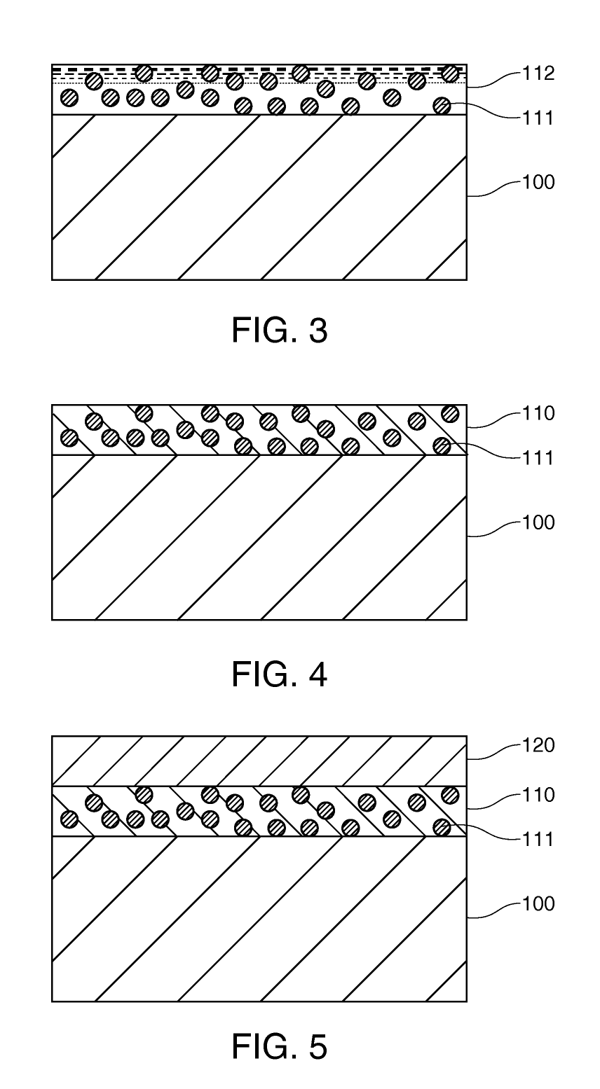

Next, a method for manufacturing the photovoltaic converter device in accordance with Embodiment 1 will be described with reference to FIGS. 3-6.

Step of Coating Silicon Precursor Liquid on P-type Single Crystalline Silicon Substrate

First, as shown in FIG. 3, a silicon precursor liquid 112 containing quantum dots 111 dispersed therein is coated on a p-type single crystalline silicon substrate 100. As the coating method, for example, a spin coat method, a spray method, or an ink jet method may be used. The precursor liquid refers to a precursor material for obtaining a specified material, and refers here to a liquid silicon material for forming an i-type semiconductor layer. As the silicon precursor liquid 112, for example, a solution liquid in which polysilane obtained through polymerization by irradiating cyclopentasilane (Si₅H₁₀) with ultraviolet light is dissolved in an organic solvent can be used.

Step of Obtaining Amorphous Silicon from Silicon Precursor Liquid

Next, the silicon precursor liquid 112 is coated on a p-type single crystalline silicon substrate 100, and heat treated by sintering in, for example, nitrogen gas, thereby forming amorphous silicon from the silicon precursor liquid 112. By this step, an i-type semiconductor layer 110 containing the quantum dots 113 dispersed therein, as shown in FIG. 4, is formed.

Step of Forming N-type Semiconductor Layer

Next, as shown in FIG. 5, an n-type semiconductor layer 120 is formed on the i-type semiconductor layer 110. In this step, first, a silicon precursor liquid (for example, the polysilane solution described above) with n-type impurity such as yellow phosphorous (P₄) added therein is coated on the i-type semiconductor layer 110 by a spin coat method. Then, the silicon precursor liquid is heat treated, thereby forming the n-type semiconductor layer 120 that is an n-type amorphous silicon layer.

Step of Forming Electrodes

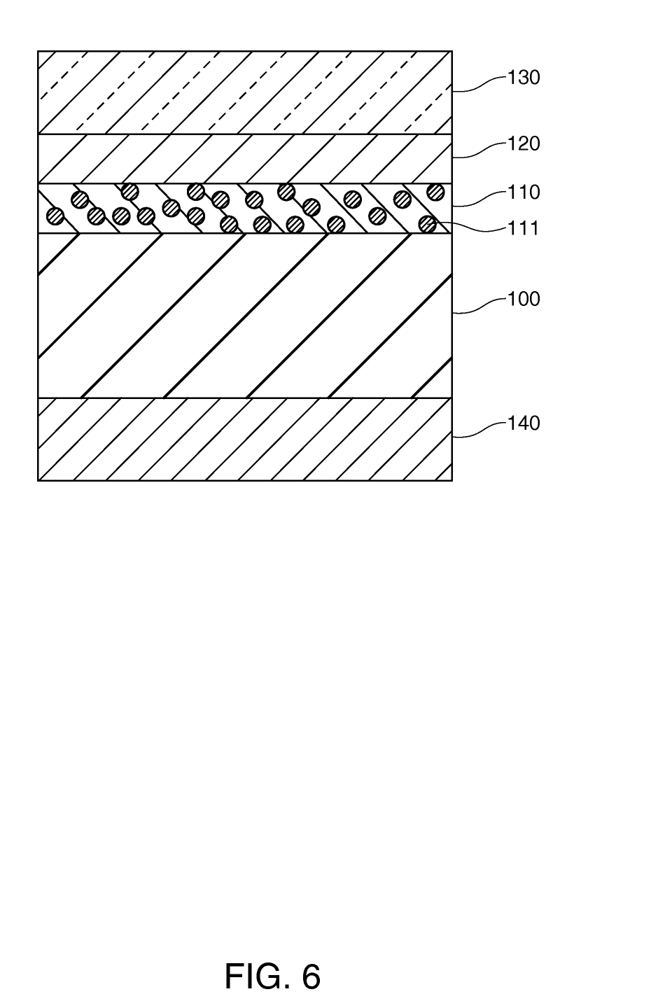

Then, as shown in FIG. 6, a transparent electrode 130 is formed on the n-type semiconductor layer 120, and a metal electrode 140 is formed below the p-type single crystalline silicon substrate 100. The transparent electrode 130 and the metal electrode 140 may both be formed by a sputtering method, a vapor deposition method, or a screen printing method.

Step of Forming Collecting Electrodes

Next, as shown in FIG. 1, collecting electrodes 150 are formed on the transparent electrode 130 and below the metal electrode 140. The collecting electrodes 150 may be formed by a sputtering method or a screen printing method.

### 3. Embodiment 2

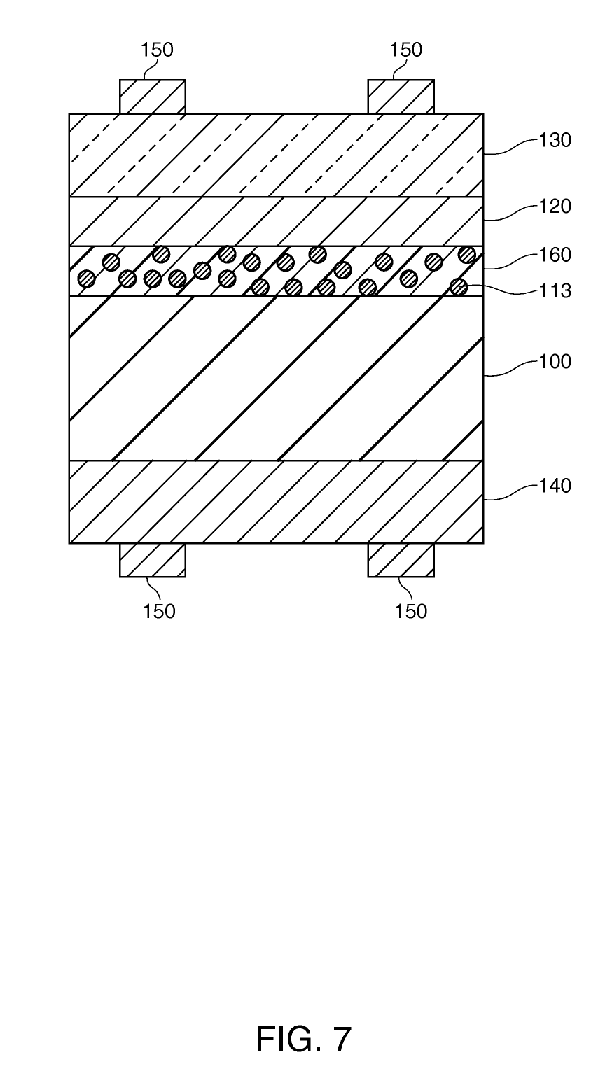

A photovoltaic converter device in accordance with Embodiment 2 will be described with reference to FIG. 7. Embodiment 2 is different from Embodiment 1 in that the i-type semiconductor layer 110 is replaced with a dielectric layer 160. Therefore the difference will be mainly described, and description of components similar to those of Embodiment 1 shall be omitted.

(1) Exemplary Structure of Photovoltaic Converter Device

FIG. 7 is a cross-sectional view showing the structure of a photovoltaic converter device in accordance with Embodiment 2. As shown in FIG. 7, the photovoltaic converter device has a structure in which a p-type single crystalline silicon substrate 100 that is a p-type (first conductivity type) semiconductor substrate, a dielectric layer 160, and an n-type semiconductor layer 120 that is an n-type (second conductivity type) semiconductor layer are laminated in layers. Furthermore, the photovoltaic converter device includes a transparent electrode 130 on the n-type semiconductor layer 120, and a metal electrode 140 below the p-type signal crystalline silicon substrate 100. Further, a plurality of collecting electrodes 150 is electrically connected to the transparent electrode 130, and a plurality of collecting electrodes 150 is electrically connected to the metal electrode 140.

The dielectric layer 160 is formed from dielectric material, containing quantum dots 113 therein. The quantum dots 113 are formed only from cores, and do not have a core-shell structure, unlike Embodiment 1. As an example, lead sulfide (PbS) may be used as the material composing the cores of the quantum dots 113. The material composing the cores is not limited to lead sulfide (PbS), but the band gap of the core of the quantum dot 113 is to be smaller than the band gap of the dielectric material forming the dielectric layer 160 in order to generate the quantum effect. The thickness of the dielectric layer 160 may be, for example, 10 nm.

(2) Method for Manufacturing Photovoltaic Converter Device

A method for manufacturing a photovoltaic converter device in accordance with Embodiment 2 will be described. However, as the steps other than the step of forming the dielectric layer 160 are similar to those of Embodiment 1, their description shall be omitted.

The dielectric layer 160 is formed through conducting two-stage sintering of the precursor liquid described in Embodiment 1. The two-stage sintering is a method in which sintering is conducted initially in nitrogen gas, and then sintering is conducted in an atmosphere containing oxygen. More specifically, sintering is conducted at 250° C. for five minutes in nitrogen gas, and then sintering is conducted in the air atmosphere at 350° C. for fifteen minutes. As a result, the silicon precursor liquid is oxidized, whereby the dielectric layer 160 composed of silicon oxide (SiO₂) that is dielectric material is formed.

### 4. Embodiment 3

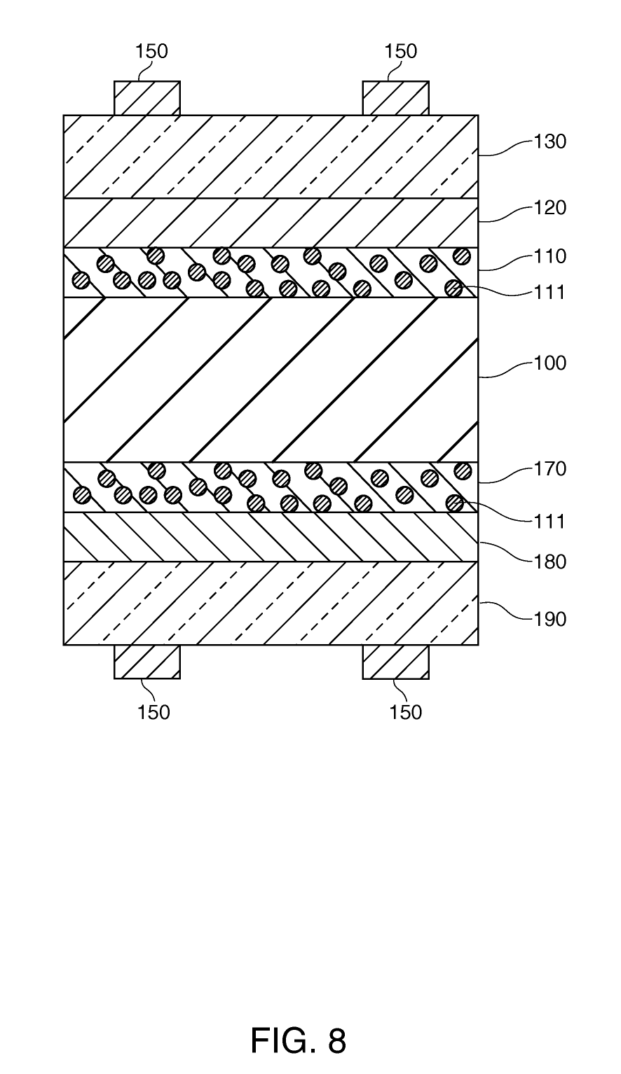

Next, a photovoltaic converter device and method for manufacturing the photovoltaic converter device in accordance with Embodiment 3 will be described with reference to FIG. 8. It is clear from comparison between Embodiment 3 and Embodiment 1, Embodiment 3 is different from Embodiment 1 in that, not only on the p-type single crystalline silicon substrate 10, an i-type semiconductor layer 170 and a high concentration p-type semiconductor layer 180 are also formed therebelow. The structure of the photovoltaic converter device in accordance with Embodiment 3 may be called a bifacial structure. The difference from Embodiment 1 will be mainly described.

(1) Exemplary Structure of Photovoltaic Converter Device

FIG. 8 is a cross-sectional view showing the structure of a photovoltaic converter device in accordance with Embodiment 3. As shown in FIG. 8, the photovoltaic converter device has a structure in which a p-type single crystalline silicon substrate 100 that is a p-type (first conductivity type) semiconductor substrate, an i-type semiconductor layer 110, and an n-type semiconductor layer 120 that is an n-type (second conductivity type) semiconductor layer are laminated in layers. Furthermore, in accordance with Embodiment 3, an i-type semiconductor layer 170 and a high concentration p-type semiconductor layer 180 that is a high concentration p-type (first conductivity type) semiconductor layer are also laminated below the p-type single crystalline silicon substrate 100. Also, transparent electrodes 130 and 190 are provided on the n-type semiconductor layer 120 and below the high concentration p-type semiconductor layer 180, respectively. Further, a plurality of collecting electrodes 150 is electrically connected to the transparent electrode 130, and a plurality of collecting electrodes 150 is electrically connected to the transparent electrode 190.

The i-type semiconductor layer 170 is formed from amorphous silicon containing quantum dots (nanoparticles) 111, like the i-type semiconductor layer 110 formed on the p-type single crystalline silicon substrate 100. The quantum dots 111 has a core-shell structure like the quantum dots 111 in accordance with Embodiment 1, and cores c and shells s thereof may be formed from the same materials as the materials used for the quantum dots contained in the upper i-type semiconductor layer 110, respectively, or one or both of the materials of the cores c and the shells s may be different from them. As the quantum dots 111, quantum dots having the same structure as that of Embodiment 1 may be used. Alternatively, the quantum dots 111 may be formed from cores c composed of germanium (Ge) particles of 3 nm in diameter, and shells s composed of germanium oxide (GeO₂) of 2 nm in thickness. The thickness of the i-type semiconductor layer 170 may be, for example, 20 nm.

The high concentration p-type semiconductor layer 180 has an impurity concentration higher than that of the p-type single crystalline silicon substrate 100, contains, for example, about 2 to 100 times more impurity, compared to the p-type semiconductor layer 180, and is formed from, for example, amorphous silicon. The thickness of the high concentration p-type semiconductor layer 180 may be, for example, 10 nm.

The transparent electrode 190 is formed from the same material as that of the transparent electrode 130. The thickness of the transparent electrode 190 may be, for example, 5 μm.

(2) Method for Manufacturing Photovoltaic Converter Device

A method for manufacturing the photovoltaic converter device in accordance with Embodiment 3 will be briefly described.

First, by the method described in Embodiment 1, a p-type single crystalline silicon substrate 100, an i-type semiconductor layer 110, an n-type semiconductor layer 120, a transparent electrode 130, and a collecting electrode 150 are formed. Then, an i-type semiconductor layer 170 is formed below the p-type single crystalline silicon substrate 100 by using the same method as the method of forming the i-type semiconductor layer 110. Next, a silicon precursor liquid with p-type impurity such as boron (B) added therein is coated below the i-type semiconductor layer 170 and then heat treated, thereby forming a high concentration p-type semiconductor layer 180 that is a p-type amorphous silicon layer. Then, a transparent electrode 190 is formed below the high concentration p-type semiconductor layer 180, and a plurality of collecting electrodes 150 is further formed below the transparent electrode 190. By the steps described above, a photovoltaic converter device shown in FIG. 8 is manufactured.

The order of forming the layers is not limited to the above, and the layers may be formed, for example, in the following order. Immediately after the i-type semiconductor layer 110 has been formed on the p-type silicon substrate 100, the i-type semiconductor layer 170 may be formed, and then the n-type semiconductor layers 120 and 180 may be formed. Further, the transparent electrodes 130 and 190 may be formed, and then the collecting electrodes 150 may be finally formed. For example, when the i-type semiconductor layer 110 and the i-type semiconductor layer 170 contain quantum dots 111 that are composed of the same materials, the i-type semiconductor layer 110 and the i-type semiconductor layer 170 may be formed at the same time.

### 5. Characteristics of the Invention

Some of the characteristics of the invention will be described in detail.

A photovoltaic converter device in accordance with an embodiment of the invention is equipped with a first conductivity type substrate (a p-type single crystalline silicon substrate 100), a first intermediate layer (an i-type semiconductor layer 110 or a dielectric layer 160), and a second conductivity type semiconductor layer (an n-type semiconductor layer 120). Further, the first intermediate layer (the i-type semiconductor layer 110 or the dielectric layer 160) includes quantum dots (nanoparticles) having at least cores. Also, the first conductivity type substrate is formed from crystalline semiconductor such as single crystalline silicon.

When the quantum dot (111) absorbs a photon with energy that is two times its band gap or greater, two carriers (excitons) may be generated from one photon. This phenomenon is called the multiple exciton generation (MEG) effect. For example, when silicon having a band gap of 1.1 eV absorbs light with high energy of 2.2 eV or greater, MEG occurs, thereby generating two excitons. Occurrence of MEG causes more carriers to be generated, which improves the conversion efficiency.

By the above-described structure in accordance with the embodiment of the invention, a photovoltaic converter device with a so-called HIT structure equipped with the first intermediate layer that is a layer containing quantum dots can be provided, without using a structure that requires a highly advanced manufacturing technology, such as, the super lattice structure. Further, by forming the first intermediate layer from semiconductor, carriers generated by MEG can be effectively retrieved, such that a photovoltaic converter device with excellent conversion efficiency can be provided.

Also, as described in Embodiment 1, the quantum dots 111 (nanoparticles) contained in the first intermediate layer (the i-type semiconductor layer 110) may preferably have a core-shell structure.

In the photovoltaic converter device with such a structure, the cores c of the quantum dots 111 are covered by the shells s, respectively. Also, the quantum dots 111 are contained in the i-type semiconductor layer 110. By this structure, as the material for the cores c, materials having an absorption coefficient higher than that of the material composing the i-type semiconductor layer 110 can be used. Accordingly, the photovoltaic converter device can be provided with higher conversion efficiency.

Further, as described above in each of the embodiments, the core c of the quantum dot (111) is coated by the shell s having a band gap greater than that of the material composing the core c. In other words, in Embodiments 1 and 4 that use the quantum dots 111 having a core-shell structure, the band gap of the shell s is greater than the band gap of the core c.

According to the photovoltaic converter device having the structure in accordance with the embodiments described above, the band gap between the material of the core c and the material of the shell s forms a quantum well, and charges within the quantum well can be readily retrieved by tunneling through the shell s. Accordingly, the photovoltaic converter device is provided with higher conversion efficiency.

Also, the absorption coefficient of the material that composes the cores c may preferably be higher than the absorption coefficient of the material included in the first intermediate layer (the i-type semiconductor layer 110).

According to such a structure, more light can be absorbed at the cores c of the quantum dots than the first intermediate layer, whereby the probability of occurrence of MEG becomes greater. Therefore the conversion coefficient of the photovoltaic converter device would be further improved.

Furthermore, the first conductivity type substrate may be a substrate of single crystalline silicon or polycrystalline silicon of a first conductivity type, the intermediate layer may be formed from i-type amorphous silicon, and the second conductivity type semiconductor layer may be formed from amorphous silicon of a second conductivity type.

Materials for the core c, the shell s and the i-type semiconductor layer 110 are selected such that the shell s has the highest band gap among them. Accordingly, the quantum effect can be effectively generated to retrieve charges, such that the conversion efficiency of the photovoltaic converter device can be improved.

It is noted that the band gap of the core c may preferably be in a range similar to that of silicon, i.e., between about 0.9 eV and about 1.4 eV, because this assures that the quantum effect can be more effectively generated.

Further, a method for manufacturing a photovoltaic converter device in accordance with an embodiment of the invention includes the steps of (1) forming a first intermediate layer (the i-type semiconductor layer 110 or the dielectric layer 160) on a first conductivity type substrate (the p-type single crystalline silicon substrate 100), and (2) forming a second conductivity type semiconductor layer (the n-type semiconductor layer 120) on the first intermediate layer. In one aspect, the first intermediate layer includes nanoparticles (quantum dots) equipped with cores, and the first conductivity type semiconductor is crystalline semiconductor.

According to such a method, the photovoltaic converter device with excellent conversion efficiency can be manufactured by using a relatively simple manufacturing method, without using a highly advanced manufacturing technology that is required for a super lattice structure.

Also, in the step of forming the second conductivity type semiconductor layer (the n-type semiconductor layer 120), it is preferred that the cores c are formed in a manner to contact the material having a band gap greater than the band gap of the core c.

According to the method described above, it is possible to manufacture a photovoltaic converter device in which the band gap between the material for the cores c and the material that contacts the cores c forms a quantum well, and charges within the quantum well can be readily retrieved by tunneling through the material that is in contact with the cores c. Accordingly, the photovoltaic converter device can be manufactured with higher conversion efficiency.

The embodiments described above are merely exemplary embodiments of the invention, and the invention includes any improvements and changes in the range that can be conceived by those skilled in the art based on the embodiments of the invention.

For example, the embodiments described above can be combined in the range that can be conceived by those skilled in the art and in the range in which they are not mutually contradictory. For example, in the photovoltaic converter device with a so-called bifacial structure shown in Embodiment 3, the i-type semiconductor layer 170 may be provided with a structure that does not include quantum dots.

The n-type semiconductor and the p-type semiconductor in the embodiments described above may be reversed in the structures. For example, the p-type single crystalline silicon substrate 100 may be reversed to an n-type single crystalline silicon substrate, the n-type semiconductor layer 120 to a p-type semiconductor layer, and the high concentration p-type semiconductor layer 180 to a high concentration n-type semiconductor layer.

In each of the embodiments, examples in which the n-type semiconductor layers 120 and 180 and the i-type semiconductor layers 110 and 170 are formed from amorphous silicon are described, but they may be formed from other semiconductor material.

In the embodiments described above, cyclopentasilane (Si₅H₁₀) is used as a silicon precursor liquid, but other silicon compound may be polymerized and used.

Further, the manufacturing conditions and the thickness of each of the layers described in the embodiments are merely examples, and the invention is not limited to those conditions and thickness.

### 6. Application Examples

The photovoltaic converter device described above may be incorporated in a variety of electronic apparatuses. There is no limitation to applicable electronic apparatuses, and some examples thereof are described below.

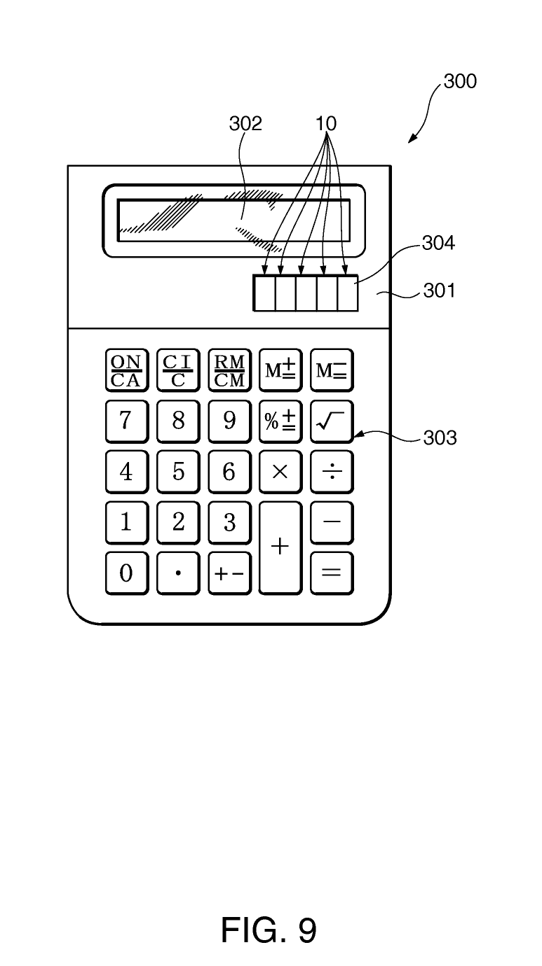

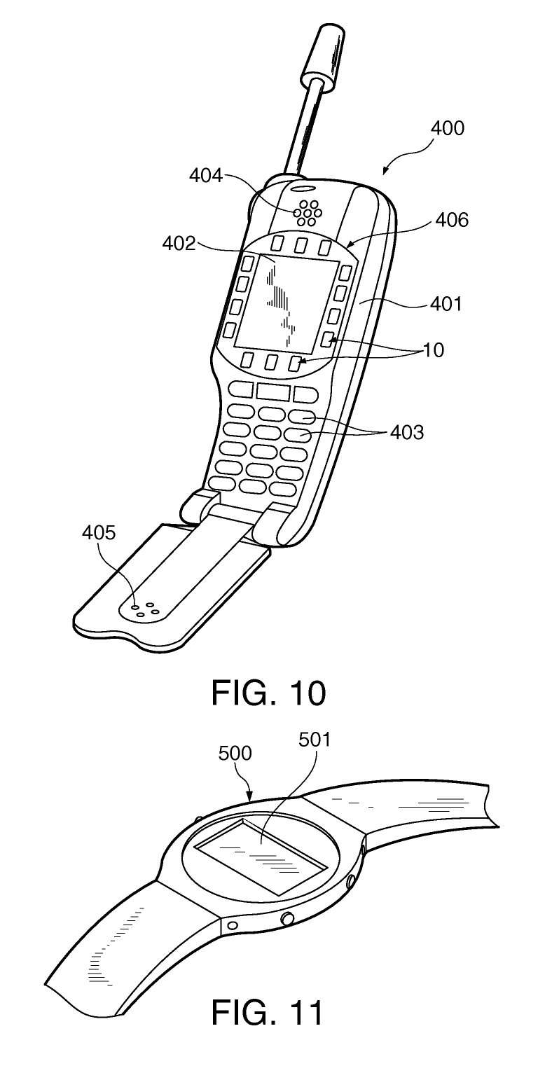

FIG. 9 is a plan view of a calculator using a solar cell (a photovoltaic converter device) in accordance with the invention. FIG. 10 is a perspective view of a cell phone (including a PHS) using a solar cell (a photovoltaic converter device) in accordance with the present invention. FIG. 11 is a perspective view of a wrist watch that is an example of an electronic apparatus.

A calculator 300 shown in FIG. 9 is equipped with a main body section 301, a display section 302 provided on an upper surface (front face) of the main body section 301, a plurality of operation buttons 303, and a photovoltaic conversion element arranged section 304.

In the composition shown in FIG. 9, five photovoltaic conversion elements 10 connected in series are arranged in the photovoltaic conversion element arrangement section 304. As the photovoltaic conversion elements 10, the photovoltaic converter devices described above can be incorporated.

A cellular phone 400 shown in FIG. 10 is equipped with a main body section 401, a display section 402 provided on a front face of the main body section 401, a plurality of operation buttons 403, a receiver section 404, a transmitter section 405 and a photovoltaic conversion element arranged section 406.

In the composition shown in FIG. 10, the photovoltaic conversion element arranged section 406 is provided in a manner to surround the display section 402, and a plurality of the photovoltaic conversion elements 10 connected in series are arranged therein. As the photovoltaic conversion elements 10, the photovoltaic converter devices described above can be incorporated.

A wrist watch 500 shown in FIG. 11 is equipped with a display section 501. For example, the photovoltaic converter device described above can be incorporated at an outer circumference of the display section 501.

It is noted that the invention is also applicable to other electronic apparatuses, such as, a photosensor, a photo switch, an electronic note pad, an electronic dictionary, a clock and the like, in addition to the calculator shown in FIG. 9, the cellular phone shown in FIG. 10 and the wrist watch shown in FIG. 11.

What is claimed is:

1. A photovoltaic converter device comprising:
a first conductivity type substrate including first conductivity type semiconductor;
a first intermediate layer formed on the first conductivity type substrate; and
a second conductivity type semiconductor layer including second conductivity type semiconductor and formed on the first intermediate layer,
the first intermediate layer including nanoparticles, the nanoparticles having cores composed of a first material.

2. A photovoltaic converter device according to claim 1, wherein at least a portion of the first conductivity type substrate is made of first conductivity type semiconductor, and at least a portion of the second semiconductor layer is made of second conductivity type semiconductor.

3. A photovoltaic converter device according to claim 1, wherein the nanoparticles have shells coating the cores and made of a second material.

4. A photovoltaic converter device according to claim 3, wherein the second material has a band gap that is greater than a band gap of the first material, and greater than a band gap of a third material included in the first intermediate layer.

5. A photovoltaic converter device according to claim 4, wherein the first material has an absorption coefficient greater than an absorption coefficient of the third material.

6. A photovoltaic converter device according to claim 4, wherein the first conductivity type substrate is a substrate of single crystal silicon or polycrystalline silicon of a first conductivity type, the third material is i-type amorphous silicon, and the second conductivity type semiconductor layer is formed from amorphous silicon of a second conductivity type.

7. A photovoltaic converter device according to claim 1, wherein the first intermediate layer includes dielectric material.

8. An electronic apparatus comprising the photovoltaic converter device recited in claim 1.

9. A method for manufacturing a photovoltaic converter device, the method comprising:
forming a first intermediate layer on a first conductivity type substrate composed of semiconductor of a first conductivity type; and
forming a second conductivity type semiconductor layer composed of semiconductor of a second conductivity type on the first intermediate layer,
the first intermediate layer including nanoparticles equipped with cores composed of a first material, and the first conductivity type semiconductor being crystalline semiconductor.

10. A method for manufacturing a photovoltaic converter device according to claim 9,
the cores being formed in contact with a material having a band gap greater than a band gap of the first material.
